(19) United States
(12) Patent Application Publication
(10) Pub. No.: US 2023/0113584 A1
(43) Pub. Date: Apr. 13, 2023

(54) METHOD FOR FORMING A PIEZOELECTRIC FILM

(71) Applicant: SKYWORKS GLOBAL PTE. LTD., Singapore (SG)

(72) Inventors: Kezia Cheng, Lowell, MA (US); Kwang Jae Shin, Yongin (KR); Alexandre Augusto Shirakawa, Cardiff by the Sea, CA (US); Stefan Bader, Fort Collins, CO (US)

(21) Appl. No.: 17/938,118

(22) Filed: Oct. 5, 2022

Related U.S. Application Data
(60) Provisional application No. 63/253,298, filed on Oct. 7, 2021.

(51) Int. Cl. H01L 41/319; H01L 41/08; H01L 41/187; H01L 41/316; H03H 9/02; H03H 9/17; H03H 9/56; H03H 9/25; H03H 9/64

(52) U.S. Cl. CPC H01L 41/319; H01L 41/0815; H01L 41/187; H01L 41/316; H03H 9/02031; H03H 9/02102; H03H 9/174; H03H 9/176; H03H 9/562; H03H 9/564; H03H 9/02929; H03H 9/25; H03H 9/64

(57) ABSTRACT

A piezoelectric film on a substrate is provided comprising an aluminum nitride (AlN) layer, and a Al₁₋ₓ(J)ₓN compound layer comprising a graded section with a lower (J) composition, x, adjacent to the AlN layer and a higher (J) composition, x, located away from the AlN layer, the said (J) being a singular element or a binary compound. A method for forming such a piezoelectric film is also provided. A surface acoustic wave resonator comprising such a piezoelectric film, a surface acoustic wave filter comprising such a piezoelectric film, a bulk acoustic wave resonator comprising such a piezoelectric film, and a bulk acoustic wave filter comprising such a piezoelectric film are also provided.

### CROSS-REFERENCE TO RELATED APPLICATIONS

This application claims priority under 35 U.S.C. § 119(e) to U.S. Provisional Patent Application Ser. No. 63/253,298, titled “METHOD FOR FORMING A PIEZOELECTRIC FILM,” filed Oct. 7, 2021, the entire contents of which is incorporated herein by reference for all purposes.

### BACKGROUND

### Field

The present disclosure generally relates to piezoelectric films, and methods for producing piezoelectric films, and particularly to piezoelectric films comprising aluminum nitride and various dopants.

### Description of Related Art

Piezoelectric films are utilized in many devices such as surface acoustic wave (SAW) and bulk acoustic wave (BAW) components, including BAW and SAW resonators and filters. Such SAW and BAW components and devices rely on piezoelectric films to transfer or store acoustic energy, and their electrical, mechanical, and electro-mechanical properties vary depending on what piezoelectric materials the piezoelectric films comprise and the thickness of the films.

One piezoelectric material that has been widely used, thanks to its manufacturability and performance levels, is aluminum nitride (AlN). In various components comprising AlN piezoelectric film, such as BAW components, the resonant frequency is dependent on the thickness of the AlN film. This means that for such components to support higher frequencies, a thinner AlN film is utilized. However, decreasing AlN film thickness leads to a decrease in the piezoelectric coefficient of the filter. One solution to compensate such loss is to introduce dopants into the AlN piezoelectric material. For example, a decrease in the piezoelectric coefficient accompanied by reducing the piezoelectric film thickness can be compensated for by doping AlN material with scandium (Sc), thereby forming an AlScN film.

The present inventors have appreciated that deposition of a thin doped AlN layer (e.g., an AlScN layer) having high concentration of dopant (e.g., Sc) by sputtering using a compound target (e.g., an AlScN compound target) is challenging as a doped AlN layer sputtered directly on a substrate is prone to crystal defects, such as mis-orientated grains, and typically has high variations in the dopant concentration and stress across the wafer (WIW stress). The present inventors have also appreciated that such a single compound target-based sputtering technique can only enable deposition of a doped AlN layer having a fixed dopant (e.g., Sc) concentration as the dopant concentration of the deposited material, in such techniques, is determined by the dopant concentration of the compound target material.

### SUMMARY

According to some embodiments, the present disclosure relates to a method of forming a piezoelectric film on a substrate comprising steps of forming, on the substrate, an aluminum nitride (AlN) layer, forming, on the AlN layer, a Al₁₋ₓ(J)ₓN compound layer comprising a graded section with a lower (J) composition, x, adjacent to the AlN layer and a higher (J) composition, x, located away from the AlN layer, (J) being a singular element or a binary compound.

Optionally the AlN layer is deposited by a first deposition technique and the Al₁₋ₓ(J)ₓN compound layer is deposited by a second different deposition technique.

Optionally the total thickness of the AlN layer, TAN, is 5 nm≤T_{AlN}≤100 nm.

Optionally (J) is one of Sc, ScB, MgZr, MgTi, MgHf, MgNb, CaSi, Y, or YB.

Optionally the portion of the Al₁₋ₓ(J)ₓN compound layer located adjacent the AlN layer has a first constant composition of (J), xᵢ.

Optionally the first constant composition, xᵢ, is xᵢ≤10 atomic percent (at. %) Optionally the Al₁₋ₓ(J)ₓN compound layer comprises a section deposited after the graded section having a second constant composition of (J), x_{f}.

Optionally the total thickness, T_{F}, of the section deposited after the graded section is 100 nm≤T_{F}≤2000 nm.

Optionally the second constant composition, x_{f}, is 20 at. %≤x_{f}≤45 at. %.

Optionally the total thickness of the graded section, T_{G}, is 5 nm≤T_{G}≤100 nm.

Optionally precursors are introduced in a sequential manner when performing the first deposition technique.

Optionally the first deposition technique provides a seed layer for the Al₁₋ₓ(J)ₓN compound layer.

Optionally the first deposition technique is performed in a self-limiting process window.

Optionally the first deposition technique is atomic layer deposition (ALD).

Optionally the first deposition technique is performed by one or more of thermal ALD or plasma enhanced ALD (PE-ALD).

Optionally the first deposition technique uses at least one of trimethylaluminum (TMA) or tris(dimethylamido)aluminum(III) as a precursor supplying Al, and at least one of ammonia (NH₃), N₂/H₂, or Hydrazine (N₂H₄) as a precursor supplying N.

Optionally the first deposition technique is performed at 50° C. to 600° C.

Optionally the grading of the (J) composition, x, is achieved by controlling the flux of (J) used when performing the second deposition technique.

Optionally the second deposition technique is one or more of sputtering, pulsed laser deposition (PLD), molecular beam epitaxy (MBE), or metal organic chemical vapor deposition (MOCVD).

Optionally the second deposition technique is reactive co-sputtering.

Optionally the reactive co-sputtering is performed using N₂ as a reactive gas, an Al target, and a target containing one of Sc, ScB, MgZr, MgTi, MgHf, MgNb, CaSi, Y, or YB.

Optionally the substrate comprises one more of silicon wafer or a metal layer.

According to some embodiments, the present disclosure relates to a piezoelectric film on a substrate, comprising an aluminum nitride (AlN) layer, and a Al₁₋ₓ(J)ₓN compound layer comprising a graded section with a lower (J) composition, x, adjacent to the AlN layer and a higher (J) composition, x, located away from the AlN layer, (J) being a singular element or a binary compound.

According to some embodiments, the present disclosure relates to a surface acoustic wave (SAW) resonator or filter comprising the piezoelectric film.

According to some embodiments, the present disclosure relates to a bulk acoustic wave (BAW) resonator or filter comprising the piezoelectric film.

According to some embodiments, the present disclosure relates to a wafer-level package that comprises the piezoelectric film, an interdigital transducer electrode on the piezoelectric film, a first thermally conductive layer arranged over the piezoelectric film and interdigital transducer electrode, and a second thermally conductive layer configured to dissipate heat generated by the surface acoustic wave device. The first thermally conductive layer is spaced apart from the piezoelectric film and interdigital transducer electrode. The second thermally conductive layer is arranged on an opposing side of the piezoelectric film to the interdigital transducer electrode.

According to a number of embodiments, the present disclosure relates to a radio frequency module that comprises a power amplifier configured to provide a radio frequency signal and a surface acoustic wave filter configured to filter the radio frequency signal. The surface acoustic wave filter includes the piezoelectric film, an interdigital transducer electrode on the piezoelectric film, a first thermally conductive layer arranged over the piezoelectric film and interdigital transducer electrode, and a second thermally conductive layer configured to dissipate heat generated by the surface acoustic wave device. The first thermally conductive layer is spaced apart from the piezoelectric film and interdigital transducer electrode. The second thermally conductive layer is arranged on an opposing side of the piezoelectric film to the interdigital transducer electrode.

According to some embodiments, the present disclosure relates to a wireless communication device that comprises a surface acoustic wave filter configured to provide a filtered radio frequency signal. The surface acoustic wave filter includes the piezoelectric film, an interdigital transducer electrode on the piezoelectric film, a first thermally conductive layer arranged over the piezoelectric film and interdigital transducer electrode, and a second thermally conductive layer configured to dissipate heat generated by the surface acoustic wave device. The first thermally conductive layer is spaced apart from the piezoelectric film and interdigital transducer electrode. The second thermally conductive layer is arranged on an opposing side of the piezoelectric film to the interdigital transducer electrode.

Embodiments disclosed herein may address various problems. One or more embodiments may address one or more of the problems concerning the composition consistency, cross-wafer composition uniformity, crystal defects, grain mis-orientation, grain uniformity, or other problems of an Al(J)N compound layer, such as an aluminum scandium nitride AlScN layer.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the disclosure. In the figures, each identical or nearly identical component that is illustrated in various figures is represented by a like numeral. For purposes of clarity, not every component may be labeled in every figure. In the figures:

FIG. 1 is a cross-section of a piezoelectric film on a substrate, comprising an aluminum nitride (AlN) layer and an Al₁₋ₓ(J)ₓN compound layer comprising a graded section;

FIG. 2 is a cross-section of the Al₁₋ₓ(J)ₓN compound layer comprising the graded section;

FIG. 3 is a cross-section of a bulk acoustic wave (BAW) structure comprising the piezoelectric film;

FIG. 4 is a flow-chart showing steps of a method of forming the piezoelectric film;

FIG. 5 is a flow-chart showing detailed steps, including optional steps, of a method of forming the piezoelectric having an Al₁₋ₓ(J)ₓN compound layer comprising an optional initial section, a graded section, and an optional final section;

FIG. 6 is a cross-section of a surface acoustic wave (SAW) structure comprising the piezoelectric film;

FIG. 7 is a schematic block diagram of a module that comprises a power amplifier, a switch, and filters;

FIG. 8 is a schematic block diagram of a module that comprises power amplifiers, switches, and filters;

FIG. 9 is a schematic block diagram of a module that comprises power amplifiers, switches, filters, and an antenna switch;

FIG. 10 is a schematic diagram of one embodiment of a wireless communication device;

FIG. 11 is a block diagram of one embodiment of a filter module that comprises the SAW structure;

FIG. 12 is a block diagram of one embodiment of a front-end module that can comprises one or more filter modules comprising the SAW structure; and

FIG. 13 is a block diagram of one embodiment of a wireless device comprising the front-end module.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Various embodiments disclosed herein provide a method of forming an improved Al(J)N layer on an AlN seed layer. Corresponding piezoelectric films and components comprising such films are also provided.

Disclosed herein are various examples related to methods of depositing a piezoelectric film comprising an Al(J)N layer which is a doped AlN layer with a dopant material (J). The dopant material (J) may be a singular element or a binary compound. The term “binary compound(s)” may be used to indicate compound(s) consisting of two different elements in any ratio. The terms “growth” and “deposition,” and “grown,” and “deposited” may be used interchangeably for the purpose of the following discussion.

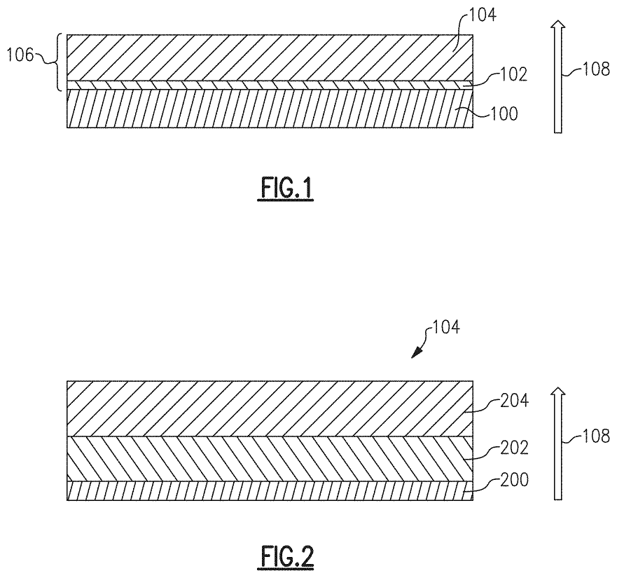

FIG. 1 is a schematic diagram of an example of a piezoelectric film 106 deposited on a substrate 100. As shown in FIG. 1 the piezoelectric film 106 comprises an AlN layer 102 on the substrate 100, and an Al(J)N layer 104 on the AlN layer 102.

The AlN layer 102 functions as a seed layer on which the Al(J)N layer 104 can be deposited. The crystal quality of such a seed layer 102 also determines the crystal quality of the following layer 104. The grain orientation of the following layer 104 may also follow the grain orientation of the seed layer 102. Therefore, it is desirable that the AlN layer 102 is deposited with low defect density, desired grain orientation, and high grain orientation uniformity.

To deposit the AlN layer 102 with high crystal quality and orientation uniformity, materials from material sources, such as precursors or/and targets, may be introduced to the surface of the substrate 100 in a sequential manner during the deposition or growth. Such a deposition or growth technique may also be self-limiting.

An example of a suitable technique for growing the high-quality AlN seed layer 102 is atomic layer deposition (ALD). During an ALD growth process, two or more precursor chemicals, each of them containing different elements of the materials being deposited, are introduced to the surface of the substrate in a sequential manner. Typically, the precursor pulses are injected into inert carrier gas, and each of the precursor pulses is separated by an inert gas purging step. During each of the precursor pulses, the reactions between the precursor molecules and the surface terminate once all reactive sites on the surface have been occupied, leading to formation of only a monolayer of material. The inert gas purging steps between the precursor pulses ensure that the precursor pulses are introduced in a non-overlapping manner, thereby preventing gas phase reactions between the precursor materials. After a full single ALD cycle, which typically comprises steps of: (i) injecting a pulse of precursor 1, (ii) purging after the precursor 1 pulse, (iii) injecting a pulse of precursor 2, and (iv) purging after the precursor 2 pulse, a single molecular layer of a compound is grown. In this manner, the ALD technique enables growth of thin and conformal films with atomic level thickness and composition precision.

Using the ALD technique discussed above or any other suitable growth or deposition technique, the AlN layer 102 may be grown at one or more deposition temperatures between 50° C. to 600° C. The ALD technique used for the AlN layer 102 growth may be thermal ALD. Alternatively, if a lower growth temperature is desirable, a plasma enhanced ALD (PEALD) technique may be used. For the AlN layer 102 growth, trimethylaluminum (TMA) and ammonia (NH₃) may be used as precursors, the TMA precursor being an aluminum source and the ammonia precursor being a nitrogen source. Inert gas, such as nitrogen, may be used as a carrier and purging gas.

The AlN layer 102 grown using the ALD technique discussed above or any other suitable growth or deposition technique may be of any thickness to enable it to function as a seed layer for the following Al(J)N layer deposition. For example, the thickness of the AlN layer 102, TAN, may be 5 nm≤T_{AlN}≤100 nm.

As shown in FIG. 1 the piezoelectric film 106 comprises the Al(J)N layer 104 on the AlN layer 102. The Al(J)N layer 104 comprises a graded section with varying compositions of Al and (J). Al(J)N compounds, which form the Al(J)N layer 104 or a part of the Al(J)N layer, with different Al/(J) ratios 104 may be represented by a formula Al₁₋ₓ(J)ₓN, x being a composition of (J) and 1-x being a composition of Al, where 0≤x<1. For example, Al_{0.25}(J)_{0.75}N represents an Al(J)N compound having 25 at. % Al and 75 at. % (J). (J) may be a singular element or a binary compound, such as Sc, ScB, MgZr, MgTi, MgHf, MgNb, CaSi, Y, or YB. (J) may be referred to as a dopant.

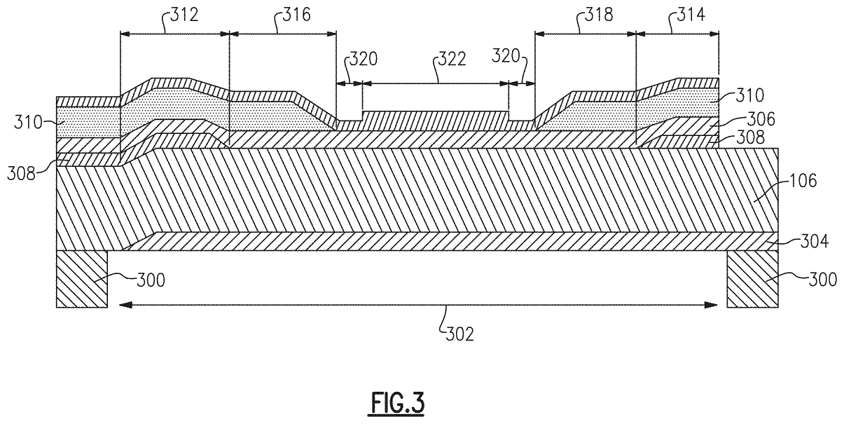

FIG. 2 is a more detailed diagram of an example of the Al(J)N layer 104 that is deposited on the AlN layer 102 of FIG. 1. As shown in FIG. 2, the Al(J)N layer 104 comprises the graded section 202. The Al(J)N layer 104 may optionally comprise a lower section 200 adjacent to the AlN layer 102. The lower section 200 of the Al(J)N layer 104 is made of a compound material Al₁₋ₓᵢ(J)ₓᵢN having a constant composition of (J), xᵢ, and a constant composition of Al, 1-xᵢ. The constant composition of (J) in the lower section 200, xᵢ, may be lower than or equal to the lowest composition of (J) in the graded portion 202. For example, the constant composition of (J) in the lower section 200, xᵢ, may be xᵢ≤0.1, meaning Al≥90 at. % and (J)≤10 at. %. Alternatively, the constant composition of (J) in the lower section 200, xᵢ, may be xᵢ=0, meaning Al=100 at. % and (J)=0 at. %. In such cases, the lower section 200 the Al(J)N layer 104 is made of the AlN compound.

The Al(J)N layer 104 may also optionally comprise an upper section 204 adjacent to the Al(J)N layer 202 and away from AlN layer 102. The upper section 204 of the Al(J)N layer 104 is made of a compound material Al_{1-xf}(J)_{xf}N having a constant composition of (J), x_{f}. and a constant composition of Al, 1-x_{f}. The constant composition of (J) in the upper section 204, x_{f}, may be higher than or equal to the highest composition of (J) in the graded portion 202. For example, the constant composition of (J) in the upper section 204, x_{f}, may be 0.2≤x_{f}≤0.24.

The graded section of the Al(J)N layer 104 comprises a graded section with varying compositions. The graded section 202 of the Al(J)N layer 104 is made of a compound material Al_{1-xg}(J)_{xg}N having graded compositions of (J), x_{g}, and graded compositions of Al, 1-x_{g}. The composition of (J) in the graded section 202, x_{g}, may change along the thickness of the graded section 202. For example, the graded section 202 may have an increasing composition of (J), x_{g}, along the growth direction 108. In such embodiments, the portion of the graded section 202 adjacent to the AlN layer 102 or adjacent to the optional lower section 200, when present, has the lowest composition of (J), xᵢ, within the graded section 202. The portion of the graded section 202 located furthest away from the AlN layer 102 in the growth direction 108 has the highest composition of (J), x_{f}, within the graded section 202. In general, the increase in the composition of (J) along the growth direction 108 may optionally comprise one or more of linear, non-linear, continuous, discrete, step, delta, and modulated profiles. The graded section 202 of the Al(J)N layer 104 may be of any thickness that can allow a gradual increase in the (J) concentration along the growth direction 108 with minimal or no deteriorations in the material quality and uniformity. For example, the thickness of the graded section 202, T_{G}, may be 5 nm≤T_{G}≤100 nm.

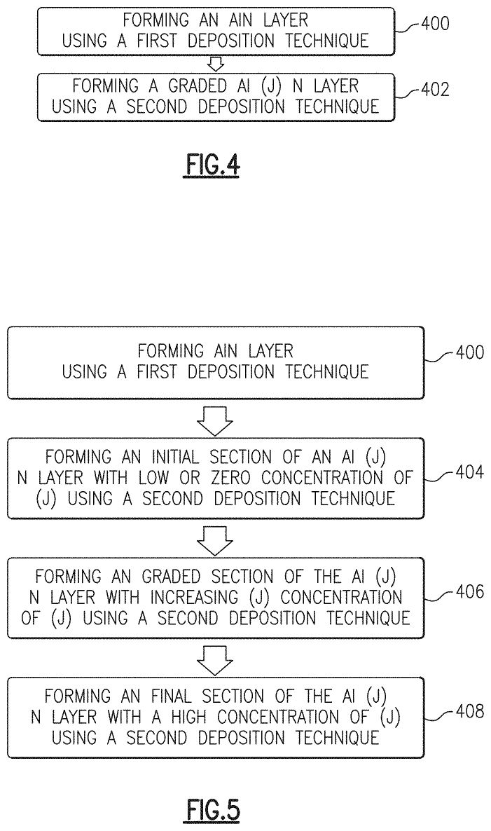

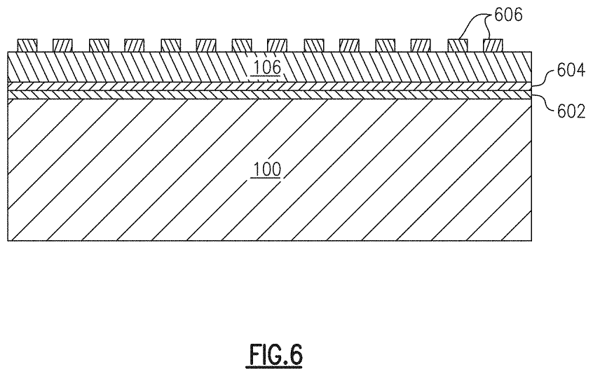

FIG. 4 and FIG. 5 are flow diagrams showing the steps of example methods for forming the piezoelectric film 106. As shown in FIG. 4 and FIG. 5, a different technique from that used for the step of forming the AlN layer 400 may be used for the step of forming the Al₁₋ₓ(J)ₓN layer 402, 404, 406, 408. For example, the AlN seed layer 102 may be deposited using an ALD technique as discussed above, and the Al₁₋ₓ(J)ₓN layer 104 may be deposited using one or more of sputtering, pulsed laser deposition (PLD), molecular beam epitaxy (MBE), or metal organic chemical vapor deposition (MOCVD). For example, following the growth of the AlN seed layer 102 using an ALD technique, the Al₁₋ₓ(J)ₓN layer 104 may be deposited using reactive co-sputtering. In such methods, the reactive co-sputtering may be performed using nitrogen as a reactive gas, an Al target, and a target containing one of Sc, ScB, MgZr, MgTi, MgHf, MgNb, CaSi, Y, or YB.

Using two different techniques for the two layers may be advantageous particularly if (i) a more efficient and scalable growth technique, other than the same growth technique used for the deposition of the AlN seed layer 102, for depositing the Al₁₋ₓᵢ(J)ₓᵢN layer 104 is available; and/or (ii) the same growth technique used for the deposition of the AlN seed layer 102 cannot be used for depositing the Al₁₋ₓᵢ(J)ₓᵢN layer 104.

The main function of the AlN layer 102 is to provide a seed layer of high crystal quality and uniformity so that such high levels of quality and uniformity can be repeated for the growth of the following layers of materials. The optional lower section 200 of the Al(J)N layer 104 can function as a buffer in which the comprising material matches that of the AlN seed layer 102, or the comprising material has a minimal compositional change from that of the AlN seed layer 102. Given that the Al(J)N layer 104 may be grown using a different deposition technique from that used for the AlN seed layer 102, providing such a buffer maximizes the probability of reproducing the high crystal quality and uniformity of the AlN seed layer 102 in the Al(J)N layer 104. The optional lower section 200 of the Al(J)N layer 104 may be of any thickness that enables such a buffered transition. For example, the thickness of the optional lower section 200, T_{I}, may be 5 nm≤T_{I}≤100 nm.

Alternatively, the Al₁₋ₓ(J)ₓN layer 104 may not comprise the optional lower section 200, and the graded section 202 may be deposited directly on the AlN seed layer 102. In such embodiments, the portion of the graded section 202 immediately adjacent to the AlN seed layer 102 may be deposited with low or no flux of (J), leading to formation of Al₁₋ₓ(J)ₓN with a low (J) concentration or AlN with zero (J). Having such a low-(J) Al₁₋ₓ(J)ₓN portion or AlN portion immediately adjacent to the AlN seed layer 102 provides a buffer in which the comprising material matches that of the AlN seed layer 102, or the comprising material has a minimal compositional change from that of the AlN seed layer 102. Such a low-(J) Al₁₋ₓ(J)ₓN portion or AlN portion immediately adjacent to the AlN seed layer 102 may be of any thickness that enables such a buffered transition.

During the growth of the Al₁₋ₓ(J)ₓN layer 104, the concentration of (J) of the deposited material may be controlled by varying the flux of (J). The flux of (J), during the deposition, may be controlled by means of one or more shutter(s) for limiting the amount of (J) molecules travelling from a material source containing (J), such as a target, to the deposition surface. The flux of (J), during the deposition, may also be controlled by changing temperature(s) of one or more part(s) of the equipment used for the material growth and/or the substrate. The flux of (J), during the deposition, may also be controlled by changing pressure(s) of one or more part(s) of the equipment used for the material growth. The flux of (J), during the deposition, may also be controlled by changing sputter power(s) of one or more material source(s), such as target(s). This enables continuous growth of the Al₁₋ₓ(J)ₓN layer 104 with varying concentration of (J) without an interruption. The relationship between the flux rate and the resulting concentration of (J) may be calculated using modelling, in-situ measurements during the growth, or post-growth measurements. Calibration involving multiple growths of Al₁₋ₓ(J)ₓN materials, each of the growths having a different concentration of (J), may be performed, particularly if the relationship is calculated by performing post-growth measurements.

Similarly, in any of the steps 402, 404, 406, 408 of growing the Al₁₋ₓ(J)ₓN layer 104 the growth rate of the material(s) deposited on the surface can be controlled by controlling one or more of: (i) one or more shutter(s), (ii) temperature of one or more part(s) of the equipment used for the material growth and/or the substrate, (iii) pressure of one or more part(s) of the equipment used for the material growth, or (iv) sputter power(s). Having a low growth rate can be beneficial for achieving high crystal quality and when precise control of thickness and composition is important. On the other hand, having a high growth rate can be beneficial for improving production yields.

As explained above, making no or minimal change in the material composition immediately after transitioning between different deposition techniques, and increasing the concentration in the graded Al₁₋ₓ(J)ₓN layer section 202 along the growth direction 108 in a gradual manner can minimize deteriorations in the material quality and uniformity. However, to maximize the benefit of introducing the dopants, (J), in the piezoelectric film 106, a significant portion or the majority of the thickness of the piezoelectric film 106 should be occupied by a Al₁₋ₓ(J)ₓN section with the high composition of (J). In such embodiments the optional upper section 204 of the Al(J)N layer 104 may be grown on the graded Al₁₋ₓ(J)ₓN layer section 202. For example, the thickness of the optional lower section 200, T_{F}, may be 100 nm≤T_{F}≤2000 nm.

The substrate 100 on which the piezoelectric film 106 is grown may comprise one more of a silicon wafer or a metal layer. Alternatively, the substrate 100 may comprise one or more of silicon, glass, quartz, or ceramic materials, such as Al₂O₃, SiN, AlN, or spinel. During any of the steps 400, 402, 404, 406, 408 of growing the piezoelectric film 106, the substrate may be mounted on a rotatable stage to improve the deposition uniformity. The stage may also comprise a heating mechanism for controlling the substrate temperature during the growth.

The piezoelectric film 106 may be used as a part of a device or a component, such as a surface acoustic wave (SAW) resonator, SAW filter, a bulk acoustic wave (BAW) resonator, a BAW filter, a solidly mounted resonator (SMR)-type BAW structure, or a lamb mode resonator on air cavity or SMR. For example, FIG. 3 shows a schematic diagram of an example BAW structure comprising the Al(J)N piezoelectric film 106. A first side of the Al(J)N piezoelectric film 106 may be connected to a substrate 300 and a first metal layer 304. The substrate 300 may optionally be partially covered with the first metal layer 304 for the first side of the Al(J)N piezoelectric film 106 to be directly connected partially to the substrate 300 and partially to the first metal layer 304. The substrate 300 may optionally comprise an air cavity 302 in its central portion. The substrate material may optionally be n-doped, p-doped, or intrinsic silicon (Si).

The BAW structure may comprise a second metal layer 306. The second metal layer 306 may comprise a first side connected to a second side of the Al(J)N piezoelectric film 106.

The BAW structure may comprise an oxide raised frame (Oxide RaF) 308 between the second side of the Al(J)N piezoelectric film 106 and the first side of the second metal layer 306. As a result, the first side of the second metal layer 306 may partially be connected to the second side of the Al(J)N piezoelectric film 106 and partially be connected to the oxide RaF 308.

The BAW structure may comprise a metal raised frame (Metal RaF) 310 connected to at least a part of the second side of the second metal layer 306.

The BAW structure may comprise a passivation layer covering the Metal RaF 310 at least a part of the second side of the second metal layer 306. As a result, the second side of the second metal layer 306 may partially be connected to the second side of the Metal RaF 310 and partially be connected to the passivation layer. The surface of the passivation layer may comprise a plurality of discontinuities, thereby forming one or more recesses. The passivation layer may comprise one or more of SiO₂, AlN, SiN, SiC, Al₂O₃, or other dielectric materials.

FIG. 6 shows a schematic diagram of an example SAW structure comprising the Al(J)N piezoelectric film 106. In such a SAW structure, the Al(J)N piezoelectric film 106 may be directly connected on the substrate 100. Alternatively, the SAW structure may comprise a trap-rich layer 602 and/or a buffer layer 604 between the Al(J)N piezoelectric film 106 and the substrate 100. The trap-rich layer 602 may be a layer having a high density of electrically active carrier traps that captures free electrons. Therefore, by having the trap-rich layer 602 within the SAW structure may significantly degrade the carrier lifetimes of the free charge carriers in the region and suppress parasitic surface conduction (PSC). The trap-rich layer 602 may, for example, comprise polysilicon (poly-Si) and/or amorphous silicon (a-Si). The buffer layer 604 may be located between the Al(J)N piezoelectric film 106 and the trap-rich layer 602. The buffer layer 604 may, for example, comprise a dielectric material such as silicon oxide or silicon nitride.

The SAW structure may also comprise one or more interdigitated transducer (IDT) fingers 606 used as electrodes. The IDT fingers 606 may be connected to a surface of the Al(J)N piezoelectric film 106. The surface of the Al(J)N piezoelectric film 106 to which the IDT fingers 606 are connected may be located away from the substrate 100, the trap-rich layer 602, and/or the buffer layer 604.

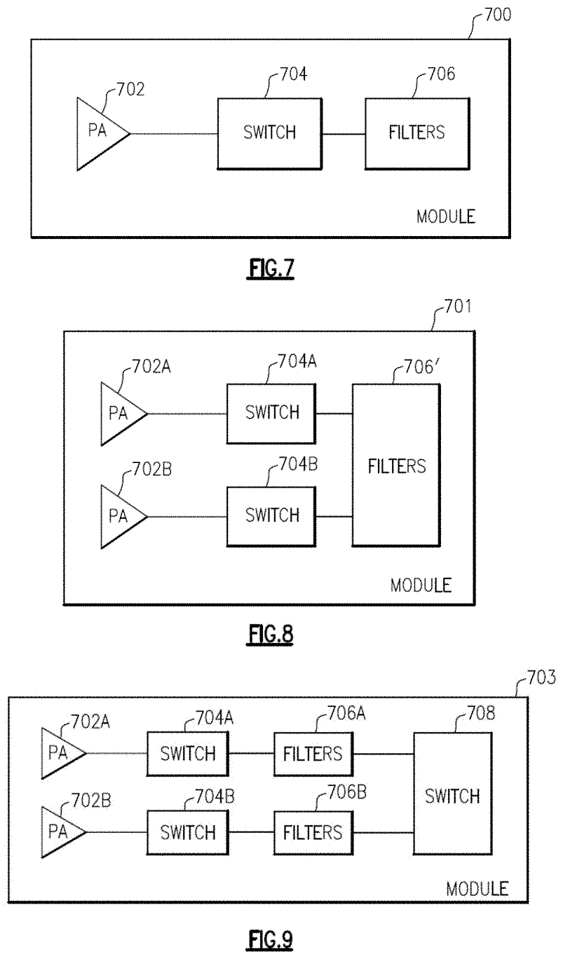

FIG. 7 is a schematic block diagram of a module 700 that includes a power amplifier 702, a switch 704, and filters 706 in accordance with one or more embodiments. The module 700 can include a package that encloses the illustrated elements. The power amplifier 702, the switch 704, and the filters 706 can be disposed on a common packaging substrate. The packaging substrate can be a laminate substrate, for example. The power amplifier 702 can amplify a radio frequency signal. The power amplifier 702 can include a gallium arsenide bipolar transistor in certain embodiments. The switch 704 can be a multi-throw radio frequency switch. The switch 704 can electrically couple an output of the power amplifier 702 to a selected filter of the filters 706. The filters 706 can include any suitable number of surface acoustic wave filters and/or other acoustic wave filters. One or more of the surface acoustic wave filters of the filters 706 can be implemented in accordance with any suitable principles and advantages of the surface acoustic wave devices discussed herein.

FIG. 8 is a schematic block diagram of a module 701 that includes power amplifiers 702A and 702B, switches 704A and 704B, and filters 706′ in accordance with one or more embodiments. The module 701 is like the module 700 of FIG. 7, except that the module 701 includes an additional power amplifier 702B and an additional switch 704B and the filters 706′ are arranged to filter signals for the signal paths associated with a plurality of power amplifiers 702A and 702B. The different signal paths can be associated with different frequency bands and/or different modes of operation (e.g., different power modes, different signaling modes, etc.).

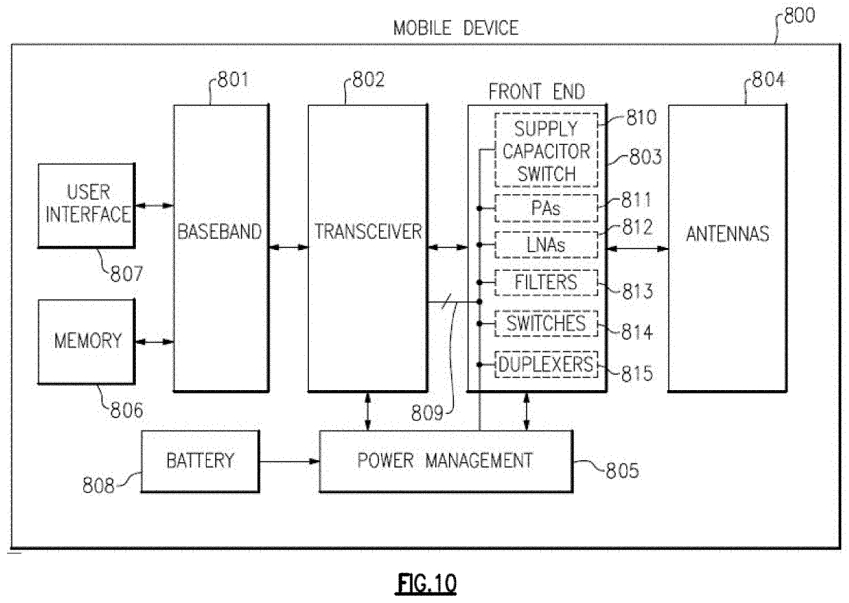

FIG. 9 is a schematic block diagram of a module 703 that includes power amplifiers 702A and 702B, switches 704A and 704B, and filters 706A and 706B in accordance with one or more embodiments, and an antenna switch 708. The module 703 is like the module 701 of FIG. 8, except the module 703 includes an antenna switch 708 arranged to selectively couple a signal from the filters 706A or the filters 706B to an antenna node. The filters 706A and 706B can correspond to the filters 706′ of FIG. 8.

FIG. 10 is a schematic diagram of one embodiment of a wireless communication device or mobile device 800. The mobile device 800 includes a baseband system 801, a transceiver 802, a front end system 803, antennas 804, a power management system 805, a memory 806, a user interface 807, and a battery 808.

Although the mobile device 800 illustrates one example of an RF system that can include one or more features of the present disclosure, the teachings herein are applicable to electronic systems implemented in a wide variety of ways.

The mobile device 800 can be used to communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 10 as the transceiver 802. In one example, separate components (for instance, separate circuits or dies) can be provided for handling certain types of RF signals.

As shown in in FIG. 10, the transceiver 802 is connected to the front end system 803 and to the power management circuit 805 using a serial interface 809. All or part of the illustrated RF components can be controlled by the serial interface 809 to configure the mobile device 800 during initialization and/or while fully operational. In another embodiment, the baseband processor 801 is additionally or alternative connected to the serial interface 809 and operates to configure one or more RF components, such as components of the front end system 803 and/or power management system 805.

The front end system 803 aids in conditioning signals transmitted to and/or received from the antennas 804. In the illustrated embodiment, the front end system 803 includes one or more bias control circuits 810 for controlling power amplifier biasing, one or more power amplifiers (PAs) 811, one or more low noise amplifiers (LNAs) 812, one or more filters 813, one or more switches 814, and one or more duplexers 815. However, other implementations are possible.

For example, the front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support multiple-input and multiple-output (MIMO) communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include phase shifters having variable phase controlled by the transceiver 802. Additionally, the phase shifters are controlled to provide beam formation and directivity for transmission and/or reception of signals using the antennas 804. For example, in the context of signal transmission, the phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 10, the baseband system 801 is coupled to the memory 806 to facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a power amplifier (PA) supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

The power management system 805 can operate in a selectable supply control mode, such an average power tracking (APT) mode or an envelope tracking (ET) mode. In the illustrated embodiment, the selected supply control mode of the power management system 805 is controlled by the transceiver 802. In certain implementations, the transceiver 802 controls the selected supply control mode using the serial interface 809.

As shown in FIG. 10, the power management system 805 receives a battery voltage from the battery 808. The battery 808 can be any suitable battery for use in the mobile device 800, including, for example, a lithium-ion battery. Although the power management system 805 is illustrated as separate from the front end system 803, in certain implementations all or part (for instance, a PA supply control circuit) of the power management system 805 is integrated into the front end system 803.

A SAW structure, such as that according to FIG. 6, may be used in SAW radio frequency (RF) filters. In turn, a SAW RF filter using one or more surface acoustic wave elements may be incorporated into and packaged as a module that may ultimately be used in an electronic device, such as a wireless communications device, for example. FIG. 11 is a block diagram illustrating one example of a module 865 including a SAW filter 850 comprising the SAW structure. The SAW filter 850 may be implemented on one or more die(s) 875 including one or more connection pads 872. For example, the SAW filter 850 may include a connection pad 872 that corresponds to an input contact for the SAW filter and another connection pad 872 that corresponds to an output contact for the SAW filter. The packaged module 865 includes a packaging substrate 880 that is configured to receive a plurality of components, including the die 875. A plurality of connection pads 882 can be disposed on the packaging substrate 880, and the various connection pads 872 of the SAW filter die 875 can be connected to the connection pads 882 on the packaging substrate 880 via electrical connectors 884, which can be solder bumps or wirebonds, for example, to allow for passing of various signals to and from the SAW filter 850. The module 865 may optionally further include other circuitry die 940, for example, one or more additional filter(s), amplifiers, pre-filters, modulators, demodulators, down converters, and the like, as would be known to one of skill in the art of semiconductor fabrication in view of the disclosure herein. Optionally, the module 865 can also include one or more packaging structures to, for example, provide protection and facilitate easier handling of the module 865. Such a packaging structure can include an overmold formed over the packaging substrate 880 and dimensioned to substantially encapsulate the various circuits and components thereon.

Various examples and embodiments of the SAW filter 850 can be used in a wide variety of electronic devices. For example, the SAW filter 850 can be used in an antenna duplexer, which itself can be incorporated into a variety of electronic devices, such as RF front-end modules and communication devices.

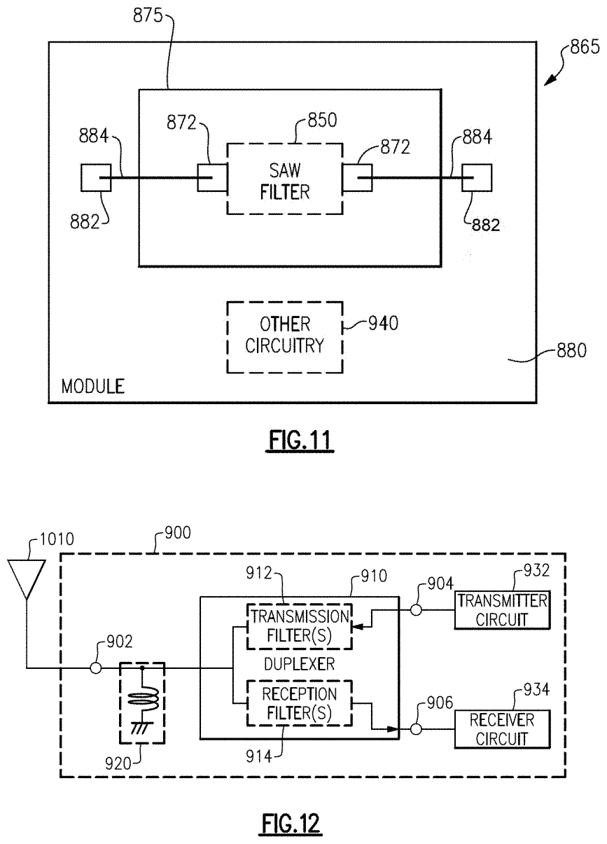

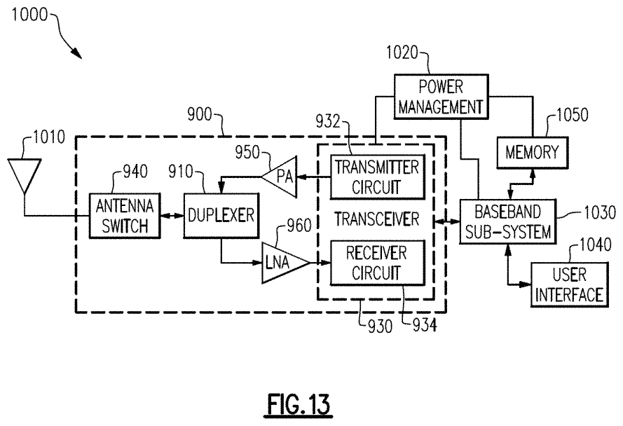

Referring to FIG. 12, there is illustrated a block diagram of one example of a front-end module 900, which may be used in an electronic device such as a wireless communications device (e.g., a mobile phone) for example. The front-end module 900 includes an antenna duplexer 910 having a common node 902, an input node 904, and an output node 906. An antenna 1010 is connected to the common node 902.

The antenna duplexer 910 may include one or more transmission filters 912 connected between the input node 904 and the common node 902, and one or more reception filters 914 connected between the common node 902 and the output node 906. The passband(s) of the transmission filter(s) are different from the passband(s) of the reception filters. Examples of the SAW filter 850 can be used to form the transmission filter(s) 912 and/or the reception filter(s) 914. An inductor or other matching component 920 may be connected at the common node 902.

The front-end module 900 further includes a transmitter circuit 932 connected to the input node 904 of the duplexer 910 and a receiver circuit 934 connected to the output node 906 of the duplexer 910. The transmitter circuit 932 can generate signals for transmission via the antenna 1010, and the receiver circuit 934 can receive and process signals received via the antenna 1010. Optionally, the receiver and transmitter circuits are implemented as separate components, as shown in FIG. 12, however, these components may optionally be integrated into a common transceiver circuit or module. As will be appreciated by those skilled in the art, the front-end module 900 may include other components that are not illustrated in FIG. 12 including, but not limited to, switches, electromagnetic couplers, amplifiers, processors, and the like.

FIG. 13 is a block diagram of one example of a wireless device 1000 including the antenna duplexer 910 shown in FIG. 12. The wireless device 1000 can be a cellular phone, smart phone, tablet, modem, communication network or any other portable or non-portable device configured for voice or data communication. The wireless device 1000 can receive and transmit signals from the antenna 1010. The wireless device includes an embodiment of a front-end module 900 similar to that discussed above with reference to FIG. 12. The front-end module 900 includes the duplexer 910, as discussed above. In the example shown in FIG. 13 the front-end module 900 further includes an antenna switch 940, which can be configured to switch between different frequency bands or modes, such as transmit and receive modes, for example. In the example illustrated in FIG. 13, the antenna switch 940 is positioned between the duplexer 910 and the antenna 1010; however, in other examples the duplexer 910 can be positioned between the antenna switch 940 and the antenna 1010. In other examples the antenna switch 940 and the duplexer 910 can be integrated into a single component.

The front-end module 900 includes a transceiver 930 that is configured to generate signals for transmission or to process received signals. The transceiver 930 can include the transmitter circuit 932, which can be connected to the input node 904 of the duplexer 910, and the receiver circuit 934, which can be connected to the output node 906 of the duplexer 910, as shown in the example of FIG. 12.

Signals generated for transmission by the transmitter circuit 932 are received by a power amplifier (PA) module 950, which amplifies the generated signals from the transceiver 930. The power amplifier module 950 can include one or more power amplifiers. The power amplifier module 950 can be used to amplify a wide variety of RF or other frequency-band transmission signals. For example, the power amplifier module 950 can receive an enable signal that can be used to pulse the output of the power amplifier to aid in transmitting a wireless local area network (WLAN) signal or any other suitable pulsed signal. The power amplifier module 950 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 950 and associated components including switches and the like can be fabricated on gallium arsenide (GaAs) substrates using, for example, high-electron mobility transistors (pHEMT) or insulated-gate bipolar transistors (BiFET), or on a silicon substrate using complementary metal-oxide semiconductor (CMOS) field effect transistors.

Still referring to FIG. 13, the front-end module 900 may further include a low noise amplifier (LNA) module 960, which amplifies received signals from the antenna 1010 and provides the amplified signals to the receiver circuit 934 of the transceiver 930.

The wireless device 1000 of FIG. 13 further includes a power management sub-system 1020 that is connected to the transceiver 930 and manages the power for the operation of the wireless device 1000. The power management system 1020 can also control the operation of a baseband sub-system 1030 and various other components of the wireless device 1000. The power management system 1020 can include, or can be connected to, a battery (not shown) that supplies power for the various components of the wireless device 1000. The power management system 1020 can further include one or more processors or controllers that can control the transmission of signals, for example. In one embodiment, the baseband sub-system 1030 is connected to a user interface 1040 to facilitate various input and output of voice and/or data provided to and received from the user. The baseband sub-system 1030 can also be connected to memory 1050 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A method for forming a piezoelectric film on a substrate, said method comprising:
forming, on the substrate, an aluminum nitride (AlN) layer;
forming, on the AlN layer, an Al₁₋ₓ(J)ₓN compound layer comprising a graded section with a lower (J) composition, x, adjacent to the AlN layer and a higher (J) composition, x, located away from the AlN layer, (J) being a singular element or a binary compound.

2. The method of claim 1 wherein the AlN layer is deposited by a first deposition technique and the Al₁₋ₓ(J)ₓN compound layer is deposited by a second different deposition technique.

3. The method of claim 2 wherein precursors are introduced in a sequential manner when performing the first deposition technique.

4. The method of claim 2 wherein the first deposition technique provides a seed layer for the Al₁₋ₓ(J)ₓN compound layer.

5. The method of claim 4 wherein the first deposition technique is performed in a self-limiting process window.

6. The method of claim 5 wherein the first deposition technique is atomic layer deposition (ALD).

7. The method of claim 4 wherein the first deposition technique is performed by one or more of thermal ALD and plasma enhanced ALD (PEALD).

8. The method of claim 2 wherein the first deposition technique uses at least one of trimethylaluminum (TMA) or tris(dimethylamido)aluminum(III) as a precursor supplying Al, and at least one of ammonia (NH₃), N₂/H₂, or Hydrazine (N₂H₄) as a precursor supplying N.

9. The method of claim 2 wherein the grading of the (J) composition, x, is achieved by controlling the flux of (J) used when performing the second deposition technique.

10. The method of claim 2 wherein the second deposition technique is one or more of sputtering, pulsed laser deposition (PLD), molecular beam epitaxy (MBE) and metal organic chemical vapor deposition (MOCVD).

11. The method of claim 2 wherein the second deposition technique is reactive co-sputtering.

12. The method of claim 1 wherein a total thickness of the AlN layer, T_{AlN}, is 5 nm≤T_{AlN}≤100 nm.

13. The method of claim 1 wherein (J) is one of Sc, ScB, MgZr, MgTi, MgHf, MgNb, CaSi, Y, or YB.

14. The method of claim 1 wherein a portion of the Al₁₋ₓ(J)ₓN compound layer located adjacent to the AlN layer has a first constant composition of (J), xᵢ.

15. The method of claim 14 wherein the first constant composition, xᵢ, is xᵢ≤10 at. %.

16. The method of claim 1 wherein the Al₁₋ₓ(J)ₓN compound layer comprises a section deposited after the graded section having a second constant composition of (J), x_{f}.

17. The method of claim 16 wherein the total thickness, T_{F}, of the section deposited after the graded section is 100 nm≤T_{F}≤2000 nm.

18. The method of claim 16 wherein the second constant composition, x_{f}, is 20 at. %≤x_{f}≤45 at. %.

19. The method of claim 1 wherein the total thickness of the graded section, T_{G}, is 5 nm≤T_{G}≤100 nm.

20. The method of claim 19 wherein the reactive co-sputtering is performed using N₂ as a reactive gas, an Al target, and a target containing one of Sc, ScB, MgZr, MgTi, MgHf, MgNb, CaSi, Y and YB.

21. A piezoelectric film on a substrate, comprising:
an aluminum nitride (AlN) layer; and
an Al₁₋ₓ(J)ₓN compound layer comprising a graded section with a lower (J) composition, x, adjacent to the AlN layer and a higher (J) composition, x, located away from the AlN layer, (J) being a singular element or a binary compound.

22. A surface acoustic wave (SAW) resonator or filter comprising the piezoelectric film of claim 21.

23. A bulk acoustic wave (BAW) resonator or filter comprising the piezoelectric film of claim 21.

24. A wireless communication device comprising:
a surface acoustic wave filter configured to provide a filtered radio frequency signal, the surface acoustic wave filter including
a piezoelectric film having an aluminum nitride (AlN) layer and an Al₁₋ₓ(J)ₓN compound layer comprising a graded section with a lower (J) composition, x, adjacent to the AlN layer and a higher (J) composition, x, located away from the AlN layer, (J) being a singular element or a binary compound,
an interdigital transducer electrode on the piezoelectric film,
a first thermally conductive layer arranged over the piezoelectric film and interdigital transducer electrode, the first thermally conductive layer being spaced apart from the piezoelectric film and interdigital transducer electrode, and
a second thermally conductive layer configured to dissipate heat generated by the surface acoustic wave device, the second thermally conductive layer being arranged on an opposing side of the piezoelectric film to the interdigital transducer electrode.
